(19) United States
(12) Patent Application Publication
(10) Pub. No.: US 2013/0189841 A1
(43) Pub. Date: Jul. 25, 2013

(54) ENGINEERING DIELECTRIC FILMS FOR CMP STOP

(71) Applicants: Mihaela Balseanu, Sunnyvale, CA (US); Li-Qun Xia, Cupertino, CA (US); Derek R. Witty, Fremont, CA (US); Thomas H. Osterheld, Mountain View, CA (US); Christopher Heung-Gyun Lee, San Jose, CA (US); William H. McClintock, Los Altos, CA (US)

(72) Inventors: Mihaela Balseanu, Sunnyvale, CA (US); Li-Qun Xia, Cupertino, CA (US); Derek R. Witty, Fremont, CA (US); Thomas H. Osterheld, Mountain View, CA (US); Christopher Heung-Gyun Lee, San Jose, CA (US); William H. McClintock, Los Altos, CA (US)

(73) Assignee: APPLIED MATERIALS, INC., Santa Clara, CA (US)

(21) Appl. No.: 13/354,939

(22) Filed: Jan. 20, 2012

(51) Int. Cl. H01L 21/306

(52) U.S. Cl. 438/692; 257/E21.23

(57) ABSTRACT

A method for forming an integrated circuit is provided. In one embodiment, the method includes forming a stop layer comprising carbon doped silicon nitride on a gate region on a substrate, the gate region having a poly gate and one or more spacers formed adjacent the poly gate, forming a dielectric layer on the stop layer, and removing a portion of the dielectric layer above the gate region using a CMP process, wherein the stop layer is a strain inducing layer having a CMP removal rate that is less than the CMP removal rate of the dielectric layer and equal to or less than the CMP removal rate of the one or more spacers.

### BACKGROUND OF THE INVENTION

1. Field of the Invention

Embodiments of the present invention generally relate to the fabrication of integrated circuits. More particularly, embodiments of the invention related to methods for depositing carbon doped silicon nitride polish stop layers having neutral, compressive, or tensile stress.

2. Description of the Related Art

Integrated circuits are composed of many, e.g., millions, of devices such as transistors, capacitors, and resistors. Such transistors may include complementary metal-oxide-semiconductor (CMOS) field effect transistors. A CMOS transistor includes a gate structure that is disposed between a source region and a drain region defined in the semiconductor substrate. The gate structure (stack) generally comprises a gate electrode formed on a gate dielectric material. The gate electrode controls a flow of charge carriers beneath the gate dielectric in a channel region that is formed between the drain region and the source region so as to turn the transistor on or off.

The performance of a CMOS device can be improved by straining the atomic lattice of materials in devices. Straining the atomic lattice improves device performance by increasing carrier mobility in a semiconductor material. The atomic lattice of one layer of a device can be strained by depositing a stressed film over the layer. For example, stressed silicon nitride layers over a gate electrode can be deposited to induce strain in the channel region of the transistor. The stressed silicon nitride layers can have compressive stress or tensile stress. The selection of a compressive or tensile stress layer is based on the type of underlying device. Typically, tensile stress layers are deposited over NMOS devices, and compressive stress layers are deposited over PMOS devices.

Additionally, as new gate formation processes are developed and device node shrinks down below 45 nm, such as to the 22 nm level, a greater ability to have conformal coverage is needed while maintaining the strain inducing capability of the layers. Although PECVD type silicon nitride films have been formed over gate electrodes as a liner layer, such films tend to be removed too quickly during chemical-mechanical polishing (CMP) type planarization processes, undesirably exposing the gate electrode to the CMP slurry and pad and degrading the gate structure. For example, during replacement gate type processes, a silicon nitride liner layer formed over the gate structure may be removed too quickly during the CMP process used to “open up” the gate structure prior to removal of a “dummy” gate. The sidewall spacers that may be formed as part of the gate structure may be exposed to the CMP process, resulting in dishing of the spacers, forming undercuts, etc. The liner layers desirably exhibit high conformality as well. Tuning layers, however, to have desired film properties has also been difficult when forming conformal silicon nitride films, particularly as the feature size decreases.

Therefore, there is a need for a process to form gate electrode structures having conformal gate polish stop layers that line the gate electrode structures and can withstand conventional CMP processes without reducing manufacturing times and provide desired stress levels to improve device performance.

### SUMMARY OF THE INVENTION

The present invention generally provides methods of forming integrated circuit devices. In one embodiment, the method includes forming a stop layer comprising carbon doped silicon nitride on a gate region on a substrate, the gate region having a poly gate and one or more spacers formed adjacent the poly gate, forming a first dielectric layer on the stop layer, removing a portion of the first dielectric layer above the gate region using a CMP process, wherein the stop layer is a strain inducing layer having a CMP removal rate that is less than the CMP removal rate of the first dielectric layer and equal to or less than the CMP removal rate of the one or more spacers.

In another embodiment the method includes forming a bulk stop layer comprising silicon nitride on a gate region on a substrate, the gate region having a poly gate and one or more spacers formed adjacent the poly gate, forming a cap stop layer comprising carbon doped silicon nitride on the bulk stop layer, forming a first dielectric layer on the cap stop layer, and removing a portion of the first dielectric layer above the gate region using a CMP process, wherein the cap stop layer is a strain inducing layer having a CMP removal rate that is less than the CMP removal rate of the first dielectric layer and equal to or less than the CMP removal rate of the one or more spacers or the bulk stop layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an exemplary substrate processing system.

FIGS. 2A-2G are side cross-sectional views that schematically illustrate different stages of a metal gate formation process according to an embodiment of the invention.

FIG. 3A-3D are side cross-sectional views that schematically illustrate different stages of a metal gate formation process according to an embodiment of the invention.

### DETAILED DESCRIPTION

Embodiments described herein generally provide methods of forming integrated circuit devices having a polish stop layer of carbon doped silicon nitride formed on a gate region of a substrate that is both a strain inducing layer and a liner layer. The stop layer may be a stressed layer having either a compressive or tensile stress while still maintaining polish stop capabilities. Tuning the stop layer to a desired type and amount of stress as well as desired polish stop capabilities may be achieved by controlling the amount of carbon in the silicon nitride layer. Additionally, the stop layer may be a conformal layer even with the presence of carbon in the silicon nitride layer. The carbon content may be tuned to improve CMP polish stop performance without degrading the film conformality and dielectric strength.

Conformality of a layer is typically quantified by a ratio (which may be represented as a percentage) of the average thickness of a layer deposited on the sidewalls of a feature to the average thickness of the same deposited layer on the field, or upper surface, of the substrate. Layers deposited by the methods described herein are observed to have a conformality of greater than about 70%, such as 85% or greater, to about 100%.

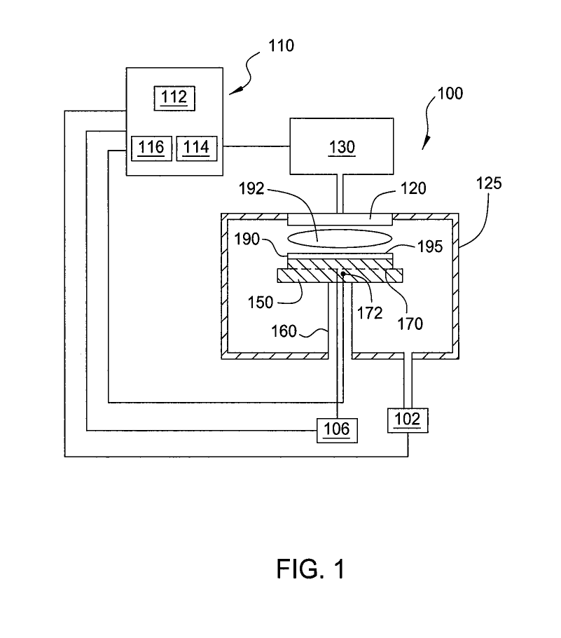

The deposition processes herein may be performed in a suitable processing system. FIG. 1 is a schematic representation of a substrate processing system, system 100, which is programmed for silicon nitride and carbon doped silicon nitride layer deposition according to embodiments of the present invention. Examples of suitable systems include the CENTURA® systems which may use a DxZ™ processing chamber, PRECISION 5000® systems, PRODUCER™ systems, such as the PRODUCER SE™ processing chamber and the PRODUCER GT™ processing chamber, all of which are commercially available from Applied Materials, Inc., Santa Clara, Calif.

System 100 includes a process chamber 125, a gas panel 130, a control unit 110, and other hardware components such as power supplies and vacuum pumps. The process chamber 125 generally comprises a substrate support pedestal 150, which is used to support a substrate such as a semiconductor substrate 190. This substrate support pedestal 150 moves in a vertical direction inside the process chamber 125 using a displacement mechanism (not shown) coupled to shaft 160. Depending on the process, the semiconductor substrate 190 can be heated to a desired temperature prior to processing. The substrate support pedestal 150 may be heated by an embedded heater element 170. For example, the substrate support pedestal 150 may be resistively heated by applying an electric current from a power supply 106 to the heater element 170. The semiconductor substrate 190 is, in turn, heated by the substrate support pedestal 150. A temperature sensor 172, such as a thermocouple, is also embedded in the substrate support pedestal 150 to monitor the temperature of the substrate support pedestal 150. The measured temperature is used in a feedback loop to control the power supply 106 for the heater element 170. The substrate temperature can be maintained or controlled at a temperature that is selected for the particular process application.

A vacuum pump 102 is used to evacuate the process chamber 125 and to maintain the proper gas flows and pressure inside the process chamber 125. A showerhead 120, through which process gases are introduced into process chamber 125, is located above the substrate support pedestal 150 and is adapted to provide a uniform distribution of process gases into process chamber 125. The showerhead 120 is connected to a gas panel 130, which controls and supplies the various process gases used in different steps of the process sequence. Process gases are described in more detail below.

The gas panel 130 may also be used to control and supply various vaporized liquid precursors. While not shown, liquid precursors from a liquid precursor supply may be vaporized, for example, by a liquid injection vaporizer, and delivered to process chamber 125 in the presence of a carrier gas. The carrier gas is typically an inert gas, such as nitrogen, or a noble gas, such as argon or helium. Alternatively, the liquid precursor may be vaporized from an ampoule by a thermal and/or vacuum enhanced vaporization process.

The showerhead 120 and substrate support pedestal 150 may also form a pair of spaced electrodes. When an electric field is generated between these electrodes, the process gases introduced into chamber 125 are ignited into a plasma 192. Typically, the electric field is generated by connecting the substrate support pedestal 150 to a source of single-frequency or dual-frequency radio frequency (RF) power (not shown) through a matching network (not shown). Alternatively, the RF power source and matching network may be coupled to the showerhead 120, or coupled to both the showerhead 120 and the substrate support pedestal 150.

PECVD techniques promote excitation and/or disassociation of the reactant gases by the application of the electric field to the reaction zone near the substrate surface, creating a plasma of reactive species. The reactivity of the species in the plasma reduces the energy required for a chemical reaction to take place, in effect lowering the required temperature for such PECVD processes.

Proper control and regulation of the gas and liquid flows through the gas panel 130 is performed by mass flow controllers (not shown) and a control unit 110 such as a computer. The showerhead 120 allows process gases from the gas panel 130 to be uniformly distributed and introduced into the process chamber 125. Illustratively, the control unit 110 comprises a central processing unit (CPU) 112, support circuitry 114, and memories containing associated control software 116. This control unit 110 is responsible for automated control of the numerous steps required for substrate processing, such as substrate transport, gas flow control, liquid flow control, temperature control, chamber evacuation, and so on. When the process gas mixture exits the showerhead 120 under plasma conditions, deposition of the precursor on the surface 195 of semiconductor substrate 190 occurs.

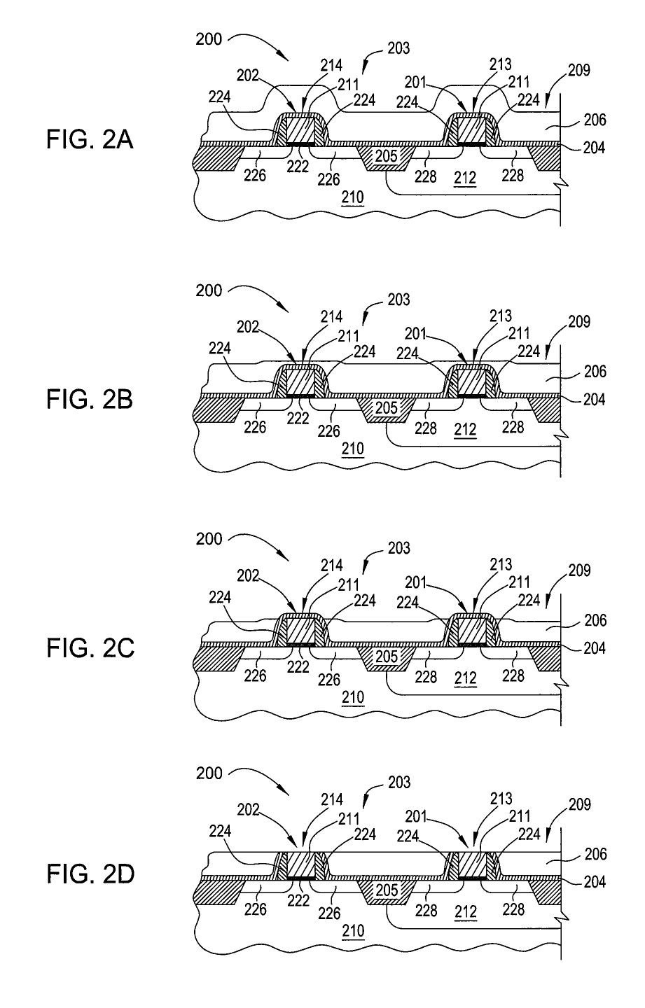

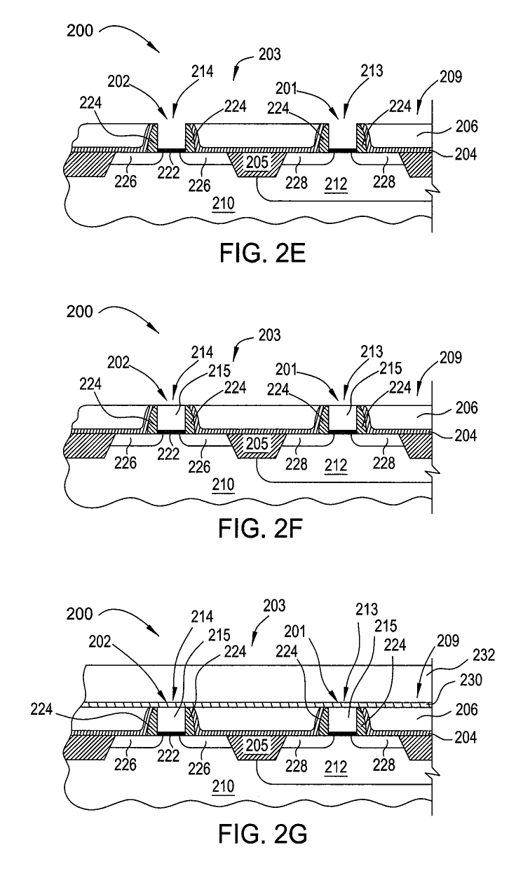

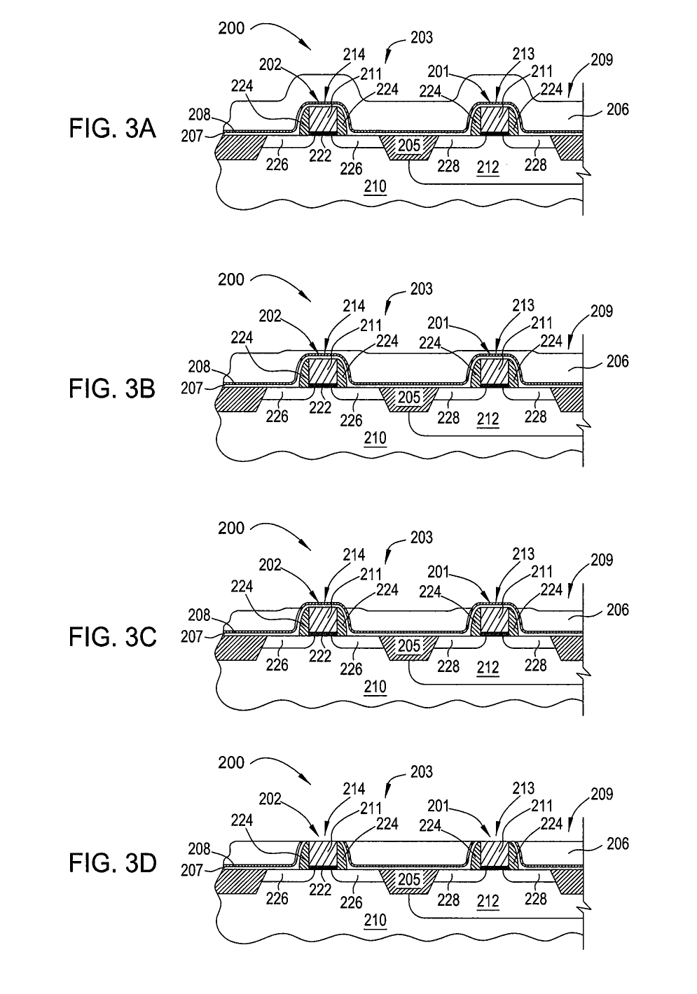

Embodiments of the invention provide for deposition of a carbon doped silicon nitride (SiₓN_{y}:C) layer that is both a strain inducing layer and a polish stop layer over a gate region having a gate structure. Aspects of the invention will be described using a “replacement metal gate” process as shown in FIGS. 2A-3D. FIGS. 2A-2G depict side cross-sectional views of a device 200 that schematically illustrates different stages of a metal gate formation process used to form PMOS and NMOS metal gates in complementary metal oxide semiconductor (CMOS) devices 201, 202 formed on a substrate. The metal gate formation stage of a device formation process can be performed in many different ways depending on the desired gate formation processing sequence, such as a gate first or gate last metal gate formation sequence. FIG. 2A schematically illustrates a stage of a replacement gate style formation sequence (i.e., gate last type sequence) in which formed dummy gates 211 (e.g., polysilicon dummy gate) are disposed in each of the gate regions (e.g., PMOS gate region 213 and NMOS gate region 214) of the PMOS device 201 and NMOS device 202. Only a portion of the gate replacement process is shown in order to illustrate applications for polish stop layers.

In this example, the CMOS device 203 comprises a PMOS device 201 and an NMOS device 202 that are separated by a field isolation region 205 formed on a portion of a substrate 210. As illustrated in FIGS. 2A-2G, the partially formed PMOS device 201 generally comprises a PMOS gate region 213 that includes a gate oxide 222, spacers 224, and a poly gate 211 that are disposed between the source-and-drain-regions 228 that are disposed in an n-well region 212 formed in the substrate 210. The partially formed NMOS device 202 generally comprises a NMOS gate region 214 that includes a gate oxide 222, spacers 224, and a poly gate 211 that are disposed between the source-and-drain-regions 226 that are disposed in the substrate 210. It should be noted that while the NMOS devices and PMOS devices are similarly illustrated and use common reference numerals in the schematic diagrams shown in FIGS. 2A-3D, this is not intended to be limiting as to the scope of the invention described herein, since each device may be configured differently.

A stop layer 204 may be formed on the PMOS and NMOS devices as shown in FIG. 2A, such as on gate regions 213, 214. The stop layer 204 may line the gate regions 213, 214. A pre-metal dielectric layer 206 is formed over the NMOS and PMOS devices and on the stop layer 204. The pre-metal dielectric layer 206 may be an oxide or low k dielectric formed using thermal and/or CVD methods including PECVD.

The stop layer 204 is a carbon doped silicon nitride film formed according to the various processes disclosed herein. The spacers 224 may be a silicon nitride film formed by processes different than the stop layer 204 formation process. For example, the spacers 224 may be a thermal nitride formed using a thermal deposition process. The stop layer 204 is configured to function as a polish stop layer when polishing the device 200 in order to “open up” the poly gate 211 as shown in FIG. 2D in order to begin the gate replacement process.

The stop layer 204 is formed by flowing a processing gas mixture comprising one or more silicon, nitrogen, and carbon containing precursors into a processing chamber having a substrate therein. A plasma is generated in the processing chamber at an RF power density from about 0.01 W/cm² to about 40 W/cm². The plasma may be formed by high frequency RF power at about 13.56 MHz, low frequency RF power at about 350 kHz, or a combination thereof, and the power level of the RF power is in the range of about 5 W to about 3000 W for a 300 mm substrate.

The precursor gas or gases provide sources of Si, N, and C. For example, Si sources may include silane (SiH₄) and tetramethylsilane (TMS). C sources may include TMS and/or CₓH_{y} hydrocarbons such as CH₄, C₂H₂, C₂H₄, C₂H₆, C₂H₂, or C₃H₄. N sources may include ammonia (NH₃), nitrogen (N₂), hydrazine (N₂H₄). Some precursors may include all three sources. For example, aminosilane compounds may be used such as alkylaminosilane, e.g., hexamethyldisilazane (HMDS), tetramethylcyclotetrasilazane, hexamethylcyclotrisilazane (HMCTZ), octamethylcyclotetrasilazanes, tris(dimethylamino)silane (TDMAS), bis-diethylamine silane (BDEAS), tetra(dimethylamino)silane (TDMAS), bis(tertiary-butylamino)silane (BTBAS), or combinations thereof. The precursors may be used in various combinations. Some examples include, but are not limited to silane, ammonia, and nitrogen; silane, TMS, and ammonia; and silane or TMS and C₂H₄ to name a few. The processing gas mixture may also include carrier gases or inert gases such as argon, helium, or xenon.

The precursor gas or gases may be introduced into the chamber at a flow rate of between about 5 sscm and about 20 slm. For example, silane may be introduced into the processing chamber at a flow rate of between about 5 sccm and about 2 slm, such as 100 sscm. If TMS is used along with silane, TMS may be introduced into the processing chamber at a flow rate of between about 5 sccm to about 100 sscm. The carbon content in the stop layer 204 increases with increasing flow of TMS. A carrier gas may be introduced into the chamber at a flow rate of between about 500 sscm and about 20,000 sscm. Nitrogen (N₂) gas, ammonia (NH₃), and/or hydrazine (N₂H₄) may be introduced into the chamber at a flow rate of between about 10 sscm and about 4,000 sscm.

During deposition of the stop layer 204 on the substrate in the chamber, the substrate is typically maintained at a temperature from about 75° C. to about 650° C., such as about 480° C. In any of the embodiments, the pressure in the chamber may be between about 50 mTorr and about 100 Torr. The stop layer may be deposited for a period of time sufficient to provide a layer thickness of between about 10 Å and about 2,500 Å, such as for about 350 seconds.

Carbon is added to the silicon nitride in the stop layer 204 in order to control the CMP removal rate. It was discovered that increasing the carbon content of the stop layer lowers the CMP removal rate of the stop layer. Adjusting the process variables such as plasma density and/or precursor type and flow rates can change the amount of carbon formed in the stop layer 204. The stop layer 204 has a carbon content from about 1 at % (atomic %) to about 20 at % such as between about 1 at % and about 10% such as about 6 at %. For example, C₂H₄ used in combination with silane or TMS can yield about 20 at % or more C in the film. In another example, increasing the flow of TMS can increase the carbon content from about 2 at % to about 15 at %.

The carbon content of the stop layer may be controlled to provide a CMP removal rate of the stop layer 204 that is less than, the CMP removal rate of the dielectric layer 206 and equal to or less than the CMP removal rate of the spacers 224 formed in the gate regions 213, 214 adjacent the poly gates 211. For example, the CMP removal rate of the stop layer 204 may match the CMP removal rate of the one or more spacers 224. In conventional liner layers formed with silicon nitride, the CMP removal rate for a neutral, compressive, or tensile stressed film would range between about 3.5 Å/min for neutral to about 5.5 Å/min and 7 Å/min for compressive and tensile SiN films respectively. The stop layer 204 formed according to embodiments of the invention, however, have a CMP removal rate from 0.5 Å/min to 2 Å/min. For comparison, the removal rate for the pre-metal dielectric layer 206 is over 500 Å/min.

CMP planarization combines both chemical and mechanical means of removing material on substrate. A CMP process removes material by simultaneously using chemical slurry that etches away material on the substrate while a pad or other abrasive mechanically removes the material. CMP processes thus have two competing effects which increases the difficulty of controlling the material removal process. The stop layer 204 formed according to embodiments of the invention accounts for those competing effects in order to decrease the etch rate so that the stop layer 204 functions as a polish stop layer.

A portion of the pre-metal dielectric layer 206 is removed using a CMP process as shown in FIG. 2B. The CMP process may use one or more polishing processes to remove the various layers on the gate region to expose the gate region for the gate replacement process. The initial removal of the dielectric layer 206 is a bulk polish CMP process that removes the bulk oxide film (dielectric layer 206) deposited on top of stop layer 204. After most of the dielectric film is removed at a high rate, a different CMP process, which may be termed a nitride polish, is run at a lower rate to remove the rest of the dielectric layer over the gate regions 213, 214 as shown in FIG. 2C. Table 1 shows the processing conditions of the bulk polish and nitride polish in a specific embodiment. Examples of suitable CMP systems include the Reflexion® LK CMP or Reflexion® GT CMP systems, all of which are commercially available from Applied Materials, Inc., Santa Clara, Calif.

TABLE 1

| Process Conditions | Bulk Polish | Nitride Polish |
|---|---|---|
| Slurry/Chemistry | Cabot SS12 | Anji L-proline/KOH |
| | (200 ml/min) | (200 ml/min) |
| Pad/Fix Abrasive Web | Dow IC1010 | 3M SWR561 |
| Head Pressure (psi) | 2 | 1.2 |
| Head RPM | 87 | 26 |
| Platen RPM | 93 | 30 |
| Pad Conditioning | 100% in situ at | N/A |
| | 9 lb down force | |

Cabot SS12 is a silica based oxide slurry but a ceria based slurry may also be utilized between a pressure range from about 1 psi to about 5 psi. The slurry flow rate may be between 150 ml/min to 300 ml/min for each slurry type. The bulk polish may use a typical ILD or STI slurry and pad. The bulk polish uses a pad while the nitride polish uses a fixed abrasive web process with L-proline/KOH chemistry at a pH adjusted to 10.5. The head pressure for the nitride polish may be between about 1 psi to about 3 psi with a platen/head rpm from 15/11 to 45/37 rpm. The nitride polish may use a high selective slurry process including fixed abrasive process since it is a stop-on-nitride process, and a fixed abrasive process may provide the best within die range performance.

Depending on the pattern density and type of oxide, the stop layer 204 may be exposed during the bulk polish and will eventually be exposed during the nitride polish. The stop layer 204 thus functions as a polish stop layer with minimal, if any, removal during the bulk and nitride polish processes. A portion of the stop layer 204 above the gate regions 213, 214 is then removed during a subsequent CMP process to “open up” or expose the poly gate 211, as shown in FIG. 2D.

The amount of carbon can also be controlled to achieve a desired type and amount of stress in the stop layer 204 in order to form stop layer 204 as a strain inducing layer as well as a polish stop layer. The stop layer may have neutral, tensile, or compressive stress. For example, the stop layer 204 may have a compressive stress from −0.05 GPa to about −3.5 GPa, such as from about −400 MPa to about −3.3 GPa. In other embodiments, the stop layer may have a tensile stress from about 0.05 GPa to about 1.7 GPa, such as about 350 MPa. Tensile stress can also be controlled by using a low plasma density when forming the stop layer such as about 0.01 W/cm². It is believed that decreasing the power density helps increase the tensile stress. Post deposition UV curing or thermal annealing may also be used to control the tensile stress in the stop layer 204. Compressive stress may be increased by using a high plasma bombardment during the deposition step, such about >1 W/cm² or by using a low frequency RF such as 350 kHz at >0.01 W/cm².

The stop layer 204 may have a conformality of 75% or greater, such as about 85%. Typically, increasing the carbon content reduces the step coverage and conformality of a film. It is believed that Si—C bond growth is more columnar resulting in reduced step coverage rather than homogeneous like Si—N growth that may provide better conformality. The addition of carbon, however, to the stop layer 204 of silicon nitride according to embodiments of the invention does not negatively affect conformality. It is believed that the conformality of the stop layer 204 is predominately given by the SiN matrix because only enough carbon is added to reduce the CMP rate by forming a few Si—C bonds compared to the Si—N bonds.

Table 2 shows some process parameters for tensile, low compressive, and high compressive carbon doped silicon nitride stop layers according to embodiments of the invention. The parameters are for a 300 mm substrate. To create a compressing nitride film, a combination of high frequency (HF) and low frequency (LF) RF is used to increase the ion bombardment.

TABLE 2

| | SiH₄ | TMS | NH₃ | Diliuent | HF RF | LF RF |
|---|---|---|---|---|---|---|
| Film Type | (sccm) | (sccm) | (sccm) | (sccm) | (W) | (W) |
| Tensile | 100 | 100 | 5000 | 8000 | 120 | 0 |
| | | | | (N₂) | | |
| Low | 200 | 100 | 1000 | 4000 | 300 | 60 |
| Compressive | | | | (N₂) | | |
| High | 50 | 50 | 200 | 3000 | 100 | 50 |
| Compressive | | | | (H₂) | | |

Table 3 shows a comparison of the properties of carbon doped silicon nitride (SiCN) layer formed with tensile, low compressive, and high compressive stress according to embodiments of the invention. As shown in Table 3, the type and amount of stress in the carbon doped silicon nitride stop layer may be controlled along with the amount of carbon. Table 3 also shows that the CMP removal rates between the films are comparable even through the amount and type of stress in each film varies.

TABLE 3

| | | Low | High |
|---|---|---|---|
| | Tensile | Compressive | Compressive |
| Film Properties | SiCN | SiCN | SiCN |
| Process Temperature (° C.) | 480 | 480 | 480 |
| Stop Layer Thickness (Å) | 200 | 200 | 200 |
| Stress (GPa) | 0.35 | −0.40 | −3.3 |
| Carbon at % | 5 | 5 | 12 |
| CMP removal rate (Å/min) | <2 | <2 | <2 |
| RI (refractive index) | 1.92 | 1.96 | 2.04 |
| WER (Å/min) (100:1 DHF) | 2.4 | 2.1 | <1.0 |
| Leakage (A/cm² at 2 MV/cm) | 3*10⁻⁹ | 5*10⁻⁹ | 1*10⁻⁹ |
| Breakdown Voltage (MV/cm) | 6.7 | 7.9 | 6.7 |

Next, as shown in FIGS. 2D and 2E, the poly gate 211 is replaced with a metal gate 215. The poly gate 211 is removed by use of conventional selective wet etching processes and the metal gate 215 is formed in both the PMOS and NMOS gate regions 213, 214 by conventional metal deposition methods such as PVD or CVD methods. Next, a contact etch stop layer 230 is formed on the gate regions 213, 214, the metal gate 215, and the dielectric layer 206. The contact etch stop layer 230 may be a carbon doped silicon nitride film formed according to embodiments disclosed herein in relation to stop layer 204. Table 4 shows some specific embodiments of the process conditions for forming the contact etch stop layer 230 and the resulting film properties. The process was carried out using a 300 mm substrate. Generally, it is desirable that the contact etch stop layer have a low etch rate and a low k, which may also be achieved by controlling the carbon content of the SiCN film.

TABLE 4

| | 350C SiCN Film | 400 C SiCN Film |
|---|---|---|
| Process Conditions | | |
| Process Temperature (° C.) | 350 | 400 |
| Pressure (T) | 3.9 | 4.4 |
| RF(W) | 360 | 360 |
| TMS (sccm) | 200 | 200 |
| NH₃ (sccm) | 1000 | 1000 |
| He (sccm) | 1200 | 800 |
| Film Properties | | |
| Deposition rate (Å/min) | 700 | 610 |
| Uniformity (1 s, %) | 0.9 | 1.0 |
| RI (refractive index) | 1.770 | 1.775 |
| WER (Å/min) (100:1 HF) | 2 | 2 |
| C content (at %) | 12 | 10 |
| Stress (MPa) | −190 | −140 |
| k (dielectric constant) | 4.5 | 4.7 |
| Vbd (MV/cm) | 8 | 7.3 |
| Leakage (A/cm² at 2 MV/cm) | 1.5*10⁻⁹ | 5.0*10⁻¹⁰ |

After formation of the contact etch stop layer 230, another dielectric layer 232 is formed on the contact etch stop layer 230. The second dielectric layer 232 may be an oxide or a low-k SiCO film. Dielectric layer 232 functions as the ILD layer for the next metal level. Table 5 shows some specific embodiments of the process conditions for forming the second dielectric layer 232 using an SiCO film and the resulting film properties. The process was carried out using a 300 mm substrate.

TABLE 5

| | 350C SiCO Film | 400 C SiCO Film |
|---|---|---|
| Process Conditions | | |
| Process Temperature (° C.) | 350 | 400 |
| Pressure (T) | 3.0 | 3.0 |
| RF1 (W) | 125 | 100 |
| RF2 (W) | 65 | 50 |
| TMS (sccm) | 70 | 70 |
| CO₂ (sccm) | 320 | 640 |
| H₂ (sccm) | 400 | 300 |
| Film Properties | | |
| Deposition rate (Å/min) | 790 | 630 |
| Uniformity (1 s, %) | 1.0 | 1.1 |
| RI (refractive index) | 1.80 | 1.73 |
| C content (at %) | X | X |
| Stress (MPa) | −280 | −265 |
| k (dielectric constant) | 4.4 | 4.4 |
| Vbd (MV/cm) | 4.5 | 5.4 |
| Leakage (A/cm² at 2 MV/cm) | 6.8*10⁻⁸ | 4.6*10⁻⁹ |

In another embodiment, a bilayer polish stop of SiN and SiCN may be formed over the gate regions 213, 214 as shown in FIGS. 3A-3D. A bulk stop layer 207 of silicon nitride may be formed on the gate regions 213, 214 as shown in FIG. 3A. The bulk stop layer 207 may be formed using thermal or PECVD type of processes and have a thickness from about 5 Å and about 500 Å, such as 200 Å. A cap stop layer 208 comprising carbon doped silicon nitride is formed on the bulk stop layer 207. The cap stop layer 208 may be formed using the processes for forming a carbon doped silicon nitride film described herein, and have a thickness from about 5 Å and about 1,000 Å, such as 300 Å. For example, the cap stop layer 208 may have a thickness that is 50% to 100% of the bulk stop layer 207 thickness. For example, if the total thickness of the bulk stop layer 207 and the cap stop layer 208 is 500 Å the cap stop layer may have a thickness from about 125 Å and about 250 Å, such as 200 Å. The bulk stop layer 207 and the cap stop layer 208 are typically deposited in the same process without vacuum break, just by changing the process gases.

The cap stop layer 208 functions as a polish stop layer during subsequent planarization of the NMOS and CMOS devices during the replacement metal gate process as shown in FIGS. 3B-3D. The cap stop layer has a CMP removal rate that is less than the CMP removal rate of the dielectric layer 206 and equal to or less than the CMP removal rate of the one or more spacers 224 or the bulk stop layer 207. The cap stop layer is also a strain inducing layer. The carbon content in the cap stop layer may be controlled to achieve a desired CMP removal rate as well as the type and amount of stress in the layer as previously described with stop layer 204.

The cap stop layer has a conformality of 75% or greater, such as 85%. The cap stop layer may have a compressive stress from about −0.01 GPa to about −3.5 GPa. The cap stop layer may have a tensile stress from about 0.01 GPa to about 1.7 GPa.

The dielectric layer 206 is removed as shown in FIGS. 3B and 3C using CMP processes, such as the bulk polish and nitride polish processes previously described. The cap layer may be exposed during the bulk polish and will eventually be exposed during the nitride polish. The cap stop layer 208 thus functions as a polish stop layer with minimal, if any, removal during the bulk and nitride polish processes. Next, a portion of the cap stop layer 208 and bulk stop layer 207 above the gate regions 213, 214 is then removed during a subsequent CMP process to “open up” or expose the poly gate 211, as shown in FIG. 3D.

It is believed that one benefit of a bilayer polish stop is that the efficiency of the CMP removal process can be improved such as by having a thinner cap stop layer 208 of SiCN which functions as the polish stop because the underlying bulk stop layer 207 of SiN has a much higher CMP removal rate than the cap stop layer 208. For example, the cap stop layer 208 CMP removal rate may be at 2 Å/min. while the bulk stop layer 207 CMP removal rate may be from 3.5 to 7 Å/min. If desired, the bulk stop layer 207 may also be a stress inducing layer if a stress higher than achieved by the cap stop layer 208 is required.

The remaining processing may be carried out as shown and described in FIGS. 2E-2G. For example, a portion of the cap stop layer 208 and the bulk stop layer 207 above above the gate regions 213, 214 may be removed to expose the poly gate 211 using a CMP process as described herein. The CMP removal process using the bilayer polish stop layer may be 2× to >10× faster than removing the single stop layer 204. For example, the CMP removal rate for a bilayer polish stop is around 3× faster than a single stop layer 204 where the total thickness is 200 Å and the bilayer has 100 Å of the SiN bulk stop layer 207 and 100 Å of the SiCN cap stop layer 208. The poly gate 211 is then replaced with a metal gate 215. A contact etch stop layer 230 may be formed on the gate regions 213, 214, the metal gate 215, and the first dielectric layer 206 as previously described. Next, a second dielectric layer 232 may be formed on the contact etch stop layer 230 as previously described.

While the foregoing is directed to embodiments of the present invention, other and further embodiments of the invention may be devised without departing from the basic scope thereof, and the scope thereof is determined by the claims that follow.

1. A method of forming an integrated circuit device, comprising:
forming a stop layer comprising carbon doped silicon nitride on a gate region on a substrate, the gate region having a poly gate and one or more spacers formed adjacent the poly gate;
forming a first dielectric layer on the stop layer; and
removing a portion of the first dielectric layer above the gate region using a CMP process, wherein the stop layer is a strain inducing layer having a CMP removal rate that is less than the CMP removal rate of the first dielectric layer and equal to or less than the CMP removal rate of the one or more spacers.

2. The method of claim 1, further comprising:
removing a portion of the stop layer above the gate region to expose the poly gate using a CMP process;
replacing the poly gate from the gate region with a metal gate;
forming a contact etch stop layer on the gate region, the metal gate, and the first dielectric layer; and
forming a second dielectric layer on the contact etch stop layer.

3. The method of claim 1, wherein the stop layer has a carbon content from about 1 at % to about 20 at %.

4. The method of claim 3, wherein the CMP removal rate of the stop layer matches the CMP removal rate of the one or more spacers.

5. The method of claim 4, wherein the stop layer has a conformality of 70% or greater.

6. The method of claim 5, wherein the stop layer has a compressive stress from about −0.01 GPa to about −3.5 GPa.

7. The method of claim 5, wherein the stop layer has a tensile stress from about 0.01 GPa to about 1.7 GPa.

8. The method of claim 1 wherein forming the stop layer on the gate region comprises:
flowing a processing gas mixture comprising one or more silicon, nitrogen, and carbon containing precursors into a processing chamber having the substrate therein;
generating a plasma in the processing chamber at an RF power density from about 0.01 W/cm² to about 40 W/cm².

9. The method of claim 8, wherein the one or more precursors are selected from the group consisting of silane (SiH₄), tetramethylsilane (TMS), CH₄, C₂H₂, C₂H₄, C₂H₆, C₂H₂, C₃H₄, ammonia (NH₃), nitrogen (N₂), hydrazine (N₂H₄), aminosilanes, hexamethyldisilazane (HMDS), hexamethylcyclotrisilazane (HMCTZ), tetramethylcyclotetrasilazane, octamethylcyclotetrasilazanes, tris(dimethylamino)silane (TDMAS), bis-diethylamine silane (BDEAS), tetra(dimethylamino)silane (TDMAS), bis(tertiary-butylamino)silane (BTBAS), or combinations thereof.

10. A method of forming an integrated circuit device, comprising:
forming a bulk stop layer comprising silicon nitride on a gate region on a substrate, the gate region having a poly gate and one or more spacers formed adjacent the poly gate;
forming a cap stop layer comprising carbon doped silicon nitride on the bulk stop layer;
forming a first dielectric layer on the cap stop layer; and
removing a portion of the first dielectric layer above the gate region using a CMP process, wherein the cap stop layer is a strain inducing layer having a CMP removal rate that is less than the CMP removal rate of the first dielectric layer and equal to or less than the CMP removal rate of the one or more spacers or the bulk stop layer.

11. The method of claim 10, further comprising:
removing a portion of the cap stop layer and the bulk stop layer above the gate region to expose the poly gate using a CMP process;
replacing the poly gate from the gate region with a metal gate;
forming a contact etch stop layer on the gate region, the metal gate, and the first dielectric layer; and
forming a second dielectric layer on the contact etch stop layer.

12. The method of claim 10, wherein the cap stop layer has a carbon content from about 1 at % to about 20 at %.

13. The method of claim 12, wherein the CMP removal rate of the cap stop layer matches the CMP removal rate of the one or more spacers.

14. The method of claim 13, wherein the cap stop layer has a conformality of 75% or greater.

15. The method of claim 14 wherein the cap stop layer has a compressive stress from about −0.01 GPa to about −3.5 GPa.

16. The method of claim 14, wherein the cap stop layer has a tensile stress from about 0.01 GPa to about 1.7 GPa.

17. The method of claim 10 wherein forming the cap stop layer on the bulk stop layer comprises:
flowing a processing gas mixture comprising one or more silicon, nitrogen, and carbon containing precursors into a processing chamber having the substrate therein;
generating a plasma in the processing chamber at an RF power density from about 0.01 W/cm² to about 40 W/cm².

18. The method of claim 17, wherein the one or more precursors are selected from the group consisting of silane (SiH₄), tetramethylsilane (TMS), CH₄, C₂H₂, C₂H₄, C₂H₆, C₂H₂, C₃H₄, ammonia (NH₃), nitrogen (N₂), hydrazine (N₂H₄), aminosilanes, hexamethyldisilazane (HMDS), hexamethylcyclotrisilazane (HMCTZ), tetramethylcyclotetrasilazane, octamethylcyclotetrasilazanes, tris(dimethylamino)silane (TDMAS), bis-diethylamine silane (BDEAS), tetra(dimethylamino)silane (TDMAS), bis(tertiary-butylamino)silane (BTBAS), or combinations thereof.

19. The method of claim 10, wherein the cap stop layer has a thickness of between about 5 Å and about 500 Å.

20. The method of claim 10, wherein the bulk stop layer has a thickness of between about 5 Å and about 1,000 Å.
